(19) United States
(12) Patent Application Publication
(10) Pub. No.: US 2024/0090255 A1
(43) Pub. Date: Mar. 14, 2024

(54) ELECTRON TRANSPORT MATERIAL AND PREPARATION METHOD THEREFOR, AND MANUFACTURING METHOD FOR DISPLAY DEVICE

(71) Applicant: TCL TECHNOLOGY GROUP CORPORATION, Guangdong (CN)

(72) Inventor: Zhenlei YAO, Guangdong (CN)

(21) Appl. No.: 18/274,341

(22) PCT Filed: Dec. 27, 2021
(86) PCT No.: PCT/CN2021/141736

§ 371 Date: Jul. 26, 2023

(30) Foreign Application Priority Data
May 17, 2021 (CN) 202110533104.9

(51) Int. Cl. H10K 50/16; H10K 50/13; H10K 71/15; H10K 71/60; H10K 85/10; H10K 85/30; H10K 85/60

(52) U.S. Cl. CPC H10K 50/16; H10K 50/13; H10K 71/15; H10K 71/60; H10K 85/111; H10K 85/381; H10K 85/631

(57) ABSTRACT

The present application discloses an electron transport material and a preparation method therefor, and a manufacturing method for a display device. The preparation method for the electron transport material includes the steps of: obtaining a metal salt solution and an alkaline solution; and after the metal salt solution and the alkaline solution are mixed, adding a capping agent in a reaction process of a metal salt and an alkaline substance to continue to react to obtain a metal oxide electron transport material having the surface thereof bonded with the capping agent, the capping agent being selected from at least one of N atom- or halogen atom-containing alkanes, N atom- or halogen atom-containing cycloalkanes, and N atom- or halogen atom-containing polymers.

### CROSS-REFERENCE TO RELATED APPLICATIONS

The present application is a U.S. national phase of International Patent Application No. PCT/CN2021/141736 with an international filing date of Dec. 27, 2021, designating the U.S., now pending, and further claims the benefit of Chinese patent application No. 202110533104.9 filed with the Chinese Patent Office on May 17, 2021, titled “Electron Transport Material and Preparation Method therefor, and Manufacturing Method for Display Device”, the entire contents each of which are incorporated herein by reference.

### TECHNICAL FIELD

The present application relates to the field of display technology, and in particular, to an electron transport material and a preparation method therefor, and a manufacturing method for a display device.

### BACKGROUND

The statements herein provide only background information relevant to the present application and do not necessarily constitute the prior art. Quantum dots (QDs) are typical nanomaterials with a particle size within the quantum confinement effect. QDs do not only possess the characteristics of bulk semiconductors, but also exhibit their own unique optical properties, specifically as: wide absorption, narrow emission, high yield of fluorescent quantum dots, good photothermal stability, etc. These unique advantages enable them to have broad application prospects in the fields of display, laser, photovoltaic, biomarker and the like. Quantum dot light-emitting diodes (QLEDs) have become a strong competitor in the field of next-generation display and lighting due to their unique optical and physical properties such as continuously adjustable light-emitting spectrum, high brightness, and high color purity. QLED devices widely adopt a sandwich structure consisting of an anode, an organic hole transport layer, a light-emitting layer, an inorganic electron transport layer, and a metal cathode. The QLED display technology prepared based on the solution method has shown great advantages and potential in the competition in the field of next-generation display applications.

At present, the commonly used synthesis method of electron transport layer materials is usually the sol-gel method. However, in the current synthesis process, there are problems of merging between nanoparticles of the electron transport material such as zinc oxide and their tendency to combine with large particles, which result in a wide distribution of particle sizes of the electron transport material and poor film formability of the solution of the electron transport material such as zinc oxide, so that the conductivity of the electron transport layer film in the device is poor.

### SUMMARY

An objective of the embodiments of the present application is to provide an electron transport material and a preparation method therefor, as well as a manufacturing method for a display device, aiming to solve at least the problem of a wide distribution of particle sizes of the electron transport material such as zinc oxide prepared by related technologies and its poor film formability, which affect the conductivity of the film of the electron transport layer.

To solve the above technical problems, the technical proposals adopted in the embodiments of the present application are as follows:

In a first aspect, there is provided a preparation method for an electron transport material, including the following steps:
obtaining a metal salt solution and an alkaline solution; and
mixing the metal salt solution and the alkaline solution, and adding a capping agent during a reaction between the metal salt and an alkaline substance to continue the reaction, so as to obtain a metal-oxide electron transport material having a surface bonded with the capping agent;
the capping agent is at least one selected from an alkane containing a N atom or a halogen atom, a cycloalkane containing a N atom or a halogen atom, and a polymer containing a N atom or a halogen atom.

In a second aspect, an electron transport material is provided, the electron transport material includes a metal oxide and a capping agent bonded to a surface of the metal oxide, the capping agent is at least one selected from an alkane containing a N atom or a halogen atom, a cycloalkane containing a N atom or a halogen atom, and a polymer containing a N atom or a halogen atom.

In a third aspect, a manufacturing method for a display device is provided, including the following steps:
stacking a hole functional layer and a light-emitting layer sequentially on a substrate containing an anode;
depositing an electron transport material prepared by the above-mentioned method or the above-mentioned electron transport material on a surface of the light-emitting layer away from the hole functional layer, carrying out a vacuum annealing to obtain an electron transport layer made of a metal oxide; and
preparing a cathode on a surface of the electron transport layer to obtain a display device;
alternatively,
depositing an electron transport material prepared by the above-mentioned method or the above-mentioned electron transport material on a surface of a cathode on a substrate, carrying out a vacuum annealing to obtain an electron transport layer made of a metal oxide; and
stacking a light-emitting layer, a hole functional layer, and an anode sequentially on a surface of the electron transport layer to obtain a display device.

The advantageous effects of the preparation method of the electron transport material provided in embodiments of the present application are that: after mixing the metal salt solution and the alkaline solution, a capping agent is added to continue the reaction during the synthesis process of the metal-oxide electron transport material, the capping agent combines with active groups such as oxygen vacancies or hydroxyl groups on the surface of metal oxide through N atoms or halogen atoms, so as to coat the surface of the nano-metal oxide, and obtain a metal-oxide electron transport material with the capping agent bonded on the surface thereof. The metal oxide nanoparticles coated by the capping agent lose their active sites, so that the probability of collision and aggregation between the nanoparticles is reduced, which reduces the aggregation of the nanoparticles and ensures the uniformity and dispersion stability of the metal oxide nanoparticles, so as to improve the film formability of the electron transport material with the film layer being more compact, which is conducive to improving the efficiency of carrier transport and migration.

The advantageous effects of the electron transport material provided by embodiments of the present application are that it includes a metal oxide and a capping agent such as an alkane, a cycloalkane, and a polymer bonded to the surface of the metal oxide through N atoms or halogen atoms. Through the passivation effect of the capping agent on the surface of the metal oxide nanomaterial, the particle size of the electron transport material is more uniform, and the stability of the metal oxide material is improved, reducing the damage of environmental factors to the metal oxide material, and thus improving the carrier transfer efficiency of the electron transport material.

The advantageous effects of the preparation method of the display device provided by embodiments of the present application are that: after depositing the above-mentioned electron transport material on the surface of the light-emitting layer or the surface of the cathode of the semi-device, vacuum annealing treatment is performed to remove the capping agent bonded to the surface of the metal-oxide nanomaterial to obtain a metal-oxide electron transport layer, followed by preparation of a cathode or preparation of a light-emitting layer, a hole functional layer and an anode in sequence on the surface of the electron transport layer to obtain a display device. The display device manufactured by the present application adopts the above-mentioned electron transport material with small and uniform particle size, so the prepared electron transport layer has good compactness and good stability, and the contact interface with the adjacent functional layer is optimized and the migration and transmission of carriers in the device are improved.

### BRIEF DESCRIPTION OF THE DRAWINGS

In order to more clearly illustrate the technical proposals in the embodiments of the present application, the following will briefly introduce the accompanying drawings that need to be used in the embodiments or exemplary technical descriptions. Obviously, the accompanying drawings in the following descriptions are only for some embodiments of the present application, those of ordinary skill in the art can also obtain other drawings based on these drawings without making creative efforts.

FIG. 1 is a flow chart of the preparation method for the electron transport material provided in an embodiment of the present application;

FIG. 2 is a schematic diagram of a conventional structure of the quantum dot light-emitting diode provided in an embodiment of the present application;

FIG. 3 is a schematic diagram of an inverted structure of the quantum dot light-emitting diode provided in an embodiment of the present application; and

FIG. 4 is a schematic structural view of the electron transport material provided by an embodiment of the present application, in which X—R is a capping agent, and X is one of N, F, Cl, Br, and I.

### DETAILED DESCRIPTION OF THE EMBODIMENTS

In order to make the technical problem to be solved, technical proposals, and beneficial effects in the present application clearer, the present application will be described in further detail in conjunction with the accompanying drawings and the embodiments. It should be understood that the specific embodiments described here are only used to explain the present application, not to limit the present application.

In the present application, the term “and/or”, which describes the association relationship of the associated objects, indicates that three relationships can exist, for example, A and/or B, which can indicate: the presence of A alone, the presence of both A and B, and the presence of B alone. Where A, B can be singular or plural.

In the present application, “at least one” means one or more, and “a plurality of” means two or more. “At least one of the following”, or the like, refers to any combination of these items, including any combination of single or plural items. For example, “at least one of a, b, or c”, or “at least one of a, b, and c”, can mean: a, b, c, a-b (i.e., a and b), a-c, b-c, or a-b-c, where a, b, c can be single or multiple, respectively.

It should be understood that in various embodiments of the present application, the size of the serial numbers of the above processes does not imply the order of execution, and some or all of the steps may be performed in parallel or sequentially, and the order of execution of the processes shall be determined by their function and inherent logic, and shall not constitute any limitation to the processes implemented in the embodiments of the present application. The terms used in the embodiments of the present application are used solely for the purpose of describing a particular embodiment and are not intended to limit the present application. The singular forms of “a” and “the” as used in the embodiments of the present application and the appended claims are also intended to include the plural forms, unless the context clearly indicates otherwise.

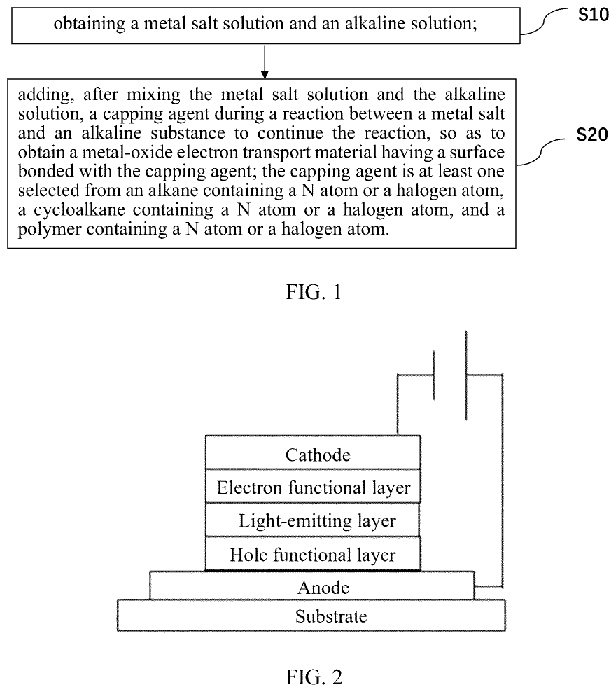

As shown in FIG. 1, the first aspect of the embodiments of the present application provides a preparation method for an electron transport material, including the following steps:
S10: obtaining a metal salt solution and an alkaline solution; and
S20: after mixing the metal salt solution and the alkaline solution, adding a capping agent during the reaction process between the metal salt and the alkaline substance to continue the reaction, so as to obtain a metal-oxide electron transport material with a capping agent bonded to the surface thereof;
the capping agent is at least one selected from an alkane containing a N atom or a halogen atom, a cycloalkane containing a N atom or a halogen atom, and a polymer containing a N atom or a halogen atom.

In the preparation method for an electron transport material provided in the first aspect of the present application, after mixing the metal salt solution and the alkaline solution, a capping agent is added during the synthesis process of the metal oxide electron transport material to continue the reaction, and the capping agent is combined with active groups such as oxygen vacancies or hydroxyl groups on the surface of the metal oxide through the N atom or the halogen atom, thereby covering the surface of the nano-metal oxide to obtain a metal-oxide electron transport material with a capping agent bonded to the surface. The metal oxide nanoparticles coated by the capping agent lost active sites, and the probability of collision and aggregation between the nanoparticles is reduced, which reduces the aggregation of the nanoparticles and ensures the uniformity and dispersion stability of the metal oxide nanoparticles, so as to improve the film formability of the electron transport material, and the film layer is more compact, which is conducive to improving the efficiency of carrier transport and migration.

In some embodiments, in the above step S10, the metal salt in the metal salt solution is at least one selected from a zinc salt, a titanium salt, a tin salt, a zirconium salt, and an indium salt. In some specific embodiments, the zinc salt includes at least one of zinc acetate and zinc chloride. In some specific embodiments, the titanium salt includes at least one of titanium acetate and titanium chloride. In some specific embodiments, the tin salt includes at least one of tin acetate and tin chloride. The metal salts used in the above embodiments of the present application all have good solubility in an organic solvent, and can react with an alkaline substance to produce a metal oxide nanomaterial in situ.

In some embodiments, the metal salt is at least one selected from a zinc salt, a titanium salt, a tin salt, a zirconium salt, and an indium salt, and the metal salt also includes at least one of a magnesium salt, an aluminum salt, a calcium salt, and a lithium salt. In the embodiments of the present application, by adding a magnesium salt, an aluminum salt, a calcium salt, a lithium salt, etc. to the reaction system, metal elements such as magnesium, aluminum, calcium, and lithium are doped in the metal oxide, which can improve the electron transport and migration performance of the metal oxide nanomaterial.

In some embodiments, the solvent in the metal salt solution is at least one selected from dimethyl sulfoxide, N,N-dimethylformamide, and tetrahydrofuran, and these organic solvents have good solubility for the metal salt of the present application, providing a suitable solvent system for the reaction between the metal salt and the alkaline substance.

In some embodiments, the alkaline substance in the alkaline solution is at least one selected from tetramethylammonium hydroxide, lithium hydroxide, potassium hydroxide, and sodium hydroxide; these alkaline substances are all capable of reacting with a metal salt to form a metal oxide nano-semiconductor material.

In some embodiments, the solvent in the alkaline solution is at least one selected from ethanol, methanol, propanol, isopropanol, and butanol, and these solvents have a good dissolution effect on alkaline substances.

In some embodiments, in the above step S20, after the metal salt reacts with the alkaline substance for 0.5 hr to 5 hrs, the particle size of metal oxide nanoparticles of ZnO, TiO₂, SnO, ZrO₂, In₂O₃, ZnMgO, AlZnO, etc. generated within the period of reaction time is small, and the capping agent is added in this reaction stage to continue the reaction until 15 hrs to 20 hrs. The capping agent is combined on the surface of metal oxide nanoparticles to inhibit the continued nucleation and growth of the metal oxides, reduce the aggregation phenomenon between nanoparticles, and ensure the uniformity and dispersion stability of metal oxide nanoparticles, thereby improving film formability of the electron transport material so that the film layer is denser, which are conducive to improving the efficiency of carrier transport and migration. In some specific embodiments, the capping agent is added after the metal salt solution and the alkaline solution are mixed and have reacted for 0.5 hrs, the capping agent is added after 1 hr, the capping agent is added after 1.5 hrs, the capping agent is added after 2 hrs, the capping agent is added after 2.5 hrs, the capping agent is added after 3 hrs, the capping agent is added after 3.5 hrs, the capping agent is added after 4 hrs, the capping agent is added after 4.5 hrs, or the capping agent is added after 5 hrs. The sooner the capping agent is added, the smaller and more uniform the particle size of the prepared metal oxide will be. If the capping agent is added too early, it will reduce the efficiency of the reaction between the metal salt and the alkaline substance to form a metal oxide. If the capping agent is added too late, the generated metal oxide particles are too large, which is not conducive to the regulation of the particle size of nanoparticles.

The capping agent used in the embodiments of the present application is at least one selected from an alkane containing a N atom or a halogen atom, a cycloalkane containing a N atom or a halogen atom, and a polymer containing a N atom or a halogen atom. On the one hand, these capping agent contains a N atom or a halogen atom, which can combine with the oxygen vacancies on the surface of the metal oxide generated in the solution system, or because a large number of hydroxyl groups are connected to the surface of the metal oxide prepared by the sol-gel method, a hydrogen bond can be formed between the capping agent and the hydroxyl group on the surface of the metal oxide and the capping agent can be bonded to the surface of the metal oxide nanoparticle to form a metal-oxide electron transport material with a capping agent bonded to the surface. On the other hand, after the electron transport material of the embodiments of the present application is deposited into a film, these capping agents can be removed from the film layer by vacuum annealing, so as to avoid the effect of the capping agent on the carrier transport performance.

In some embodiments, in the capping agent, the number of carbon atoms of the alkane containing a N atom or a halogen atom is 2 to 16; the number of carbon atoms of the cycloalkane containing a N atom or a halogen atom is 3 to 16. In some embodiments, the alkane contains a branched chain. In the embodiment of the present application, the number of carbon atoms of the alkane capping agent is selected from 2 to 16, and the number of carbon atoms of cycloalkane is selected from 3 to 16, such that the capping agent can effectively block the growth and aggregation of the metal oxide, thereby obtaining a metal oxide with a small and uniform particle size. If the carbon chain of the capping agent is too long, the viscosity of the capping agent is too high, or it is unable to be fully dissolved in the reaction system. In addition, this is also unfavorable for the capping agent to be removed by vacuum annealing in the subsequent device fabrication process.

In some embodiments, the polymer containing a N atom or a halogen atom can be better dissolved in the reaction system, and have a lower boiling point of no higher than 300° C., which is beneficial for the removal by vacuum annealing in the subsequent device fabrication process.

In some specific embodiments, the capping agent is at least one selected from diethylamine, chlorobenzene, bromobenzene, and polyvinylpyrrolidone. These capping agents have good solubility, good binding performance with the surface of metal oxides, and are easily removed by vacuum annealing.

In some embodiments, after the metal salt solution and the alkaline solution are mixed, the molar ratio of the metal salt to the alkaline substance in the mixed solution is 1:(1.2-1.8). the metal salt and the alkaline substance can react well to form a metal oxide under this molar ratio. If the proportion of the alkaline substance is too high, the excess alkaline substance will combine with the metal element to form alkali metal precipitation, which reduces the generation efficiency of the metal oxide nanomaterial, resulting in a low purity which will affect the subsequent coating of the capping agent on the metal oxide nanomaterial. In some specific embodiments, after mixing the metal salt solution and the alkaline solution, the molar ratio of the metal salt to the alkaline substance in the mixed solution may be 1:1.2, 1:1.5, 1:1.6, 1:1.8, etc.

In some embodiments, the step of mixing the metal salt solution and the alkaline solution includes: adding the alkaline solution dropwise to the metal salt solution at a temperature of 40° C. to 60° C., allowing the added alkaline substance and the metal salt to react and produce a metal oxide. If too much alkaline substance is added at one time or the addition speed is too fast, the excess alkaline substance added at one time cannot fully react with the metal salt to form a metal oxide and will easily combine with the metal element to form alkali metal precipitation.

The preparation method for the electron transport material in the embodiments of the present application can be used to prepare electron transport materials in the following embodiments.

As shown in FIG. 4, the second aspect of the embodiments of the present application provides an electron transport material, including a metal oxide and a capping agent bonded to a surface of the metal oxide, the capping agent is at least one selected from an alkane containing a N atom or a halogen atom, a cycloalkane containing a N atom or a halogen atom, and a polymer containing a N atom or a halogen atom.

The electron transport material provided by the second aspect of the present application includes a metal oxide, and a capping agent such as an alkane, a cycloalkane, and a polymer that are bonded to the surface of metal oxide through a N atom or a halogen atom. Through the passivation effect of the capping agent on the surface of the material, the particle size of the electron transport material is more uniform, the stability of the metal oxide material is improved, and reduces the damage of environmental factors to the metal oxide material, thus increasing the carrier migration and transfer efficiency of the electron transport material.

In some embodiments, the particle size of the electron transport material is 1 μm-25 μm, and the particle size is small and uniform, which can improve the film density and uniformity of the electron transport layer, thereby improving the stability of the film layer.

In some embodiments, the metal oxide includes at least one of ZnO, TiO₂, SnO, ZrO₂, In₂O₃, ZnMgO, and AlZnO, and these metal-oxide electron transport materials have high electron transfer efficiency.

In some embodiments, the capping agent is at least one selected from diethylamine, chlorobenzene, bromobenzene, and polyvinylpyrrolidone.

The third aspect of the embodiments of the present application provides a method for manufacturing a display device, including the following steps:
S30: sequentially stacking a hole functional layer and a light-emitting layer on a substrate containing an anode;
S40: after depositing the above-mentioned electron transport material on a surface of the light-emitting layer away from the hole functional layer, carrying out a vacuum annealing treatment to obtain an electron transport layer made of a metal oxide; and
S50: preparing a cathode on a surface of the electron transport layer to obtain a display device;
alternatively,
S60: after depositing the above-mentioned electron transport material on a surface of a cathode on a substrate, carrying out a vacuum annealing treatment to obtain an electron transport layer made of a metal oxide; and
S70: sequentially stacking a light-emitting layer, a hole functional layer, and an anode on a surface of the electron transport layer to obtain a display device.

In the preparation method for the display device provided by the third aspect of the present application, after depositing the above-mentioned electron transport material on the surface of a light-emitting layer or the surface of a cathode of the semi-device, a vacuum annealing treatment is performed to remove the capping agent bonded to the surface of the metal oxide nanomaterial to obtain an electron transport layer made of a metal oxide, and then a cathode is prepared or a light emitting layer, a hole functional layer and an anode are sequentially prepared on the surface of the electron transport layer to obtain a display device. The display device prepared in the embodiment of the present application adopts the above-mentioned electron transport material with small and uniform particle size, so the prepared electron transport layer has good compactness and good stability, and the contact interface with the adjacent functional layer is optimized, thereby improving the migration and transport of carriers within the device.

In some embodiments, the step of preparing the electron transport layer includes: on the surface of the light-emitting layer or the cathode, depositing a solution of the above-mentioned electron transport material at a certain concentration into a film through a process such as drop coating, spin coating, immersing, plastic coating, printing, and evaporation, while the thickness of the electron transport layer being controlled to be about 20 nm-60 nm by adjusting the concentration of the solution, the deposition speed (for example, the rotation speed is between 3000 rpm-5000 rpm) and the deposition time, and then annealing at a temperature of 70° C.-90° C. for 0.5-2 hrs under a vacuum degree no higher than 0.0001 Pa to form a film and fully remove the solvent and the surface-bonded capping agent.

In some embodiments, the metal oxide includes at least one of ZnO, TiO₂, SnO, ZrO₂, In₂O₃, ZnMgO, and AlZnO, and the particle size is 1 μm-25 μm.

In some embodiments, in order to obtain a high-quality light-emitting device, the substrate often needs to undergo a pretreatment process. The pretreatment step includes: washing the substrate such as an ITO conductive glass with a cleaning agent to initially remove the stains on the surface, followed by ultrasonic washing with deionized water, acetone, absolute ethanol, and deionized water sequentially and respectively for 20 min to remove impurities on the surface, and finally dried with high-purity nitrogen gas to obtain the ITO cathode.

In some embodiments, the selection of the substrate is not limited, and a rigid substrate or a flexible substrate may be used. In some specific embodiments, the rigid substrate includes, but is not limited to, one or more of glass and a metal foil. In some specific embodiments, the flexible substrate includes, but is not limited to, one or more of polyethylene terephthalate (PET), polyethylene naphthalate (PEN), polyether ether ketone (PEEK), polystyrene (PS), polyethersulfone (PES), polycarbonate (PC), polyarylate (PAT), polyarylate (PAR), polyimide (PI), polyvinyl chloride (PV), polyethylene (PE), polyvinylpyrrolidone (PVP), and textile fibers.

In some embodiments, in the above steps, the selection of anode material is not limited, and the anode material may be selected from doped metal oxides, including but not limited to one or more of indium-doped tin oxide (ITO), fluorine-doped tin oxide (FTO), antimony-doped tin oxide (ATO), aluminum-doped zinc oxide (AZO), gallium-doped zinc oxide (GZO), indium-doped zinc oxide (IZO), magnesium-doped zinc oxide (MZO), and aluminum-doped magnesium oxide (AMO). It may also be selected from composite electrodes having a metal sandwiched between doped or undoped transparent metal oxides, including but not limited to one or more of AZO/Ag/AZO, AZO/Al/AZO, ITO/Ag/ITO, ITO/Al/ITO, ZnO/Ag/ZnO, ZnO/A1/ZnO, TiO₂/Ag/TiO₂, TiO₂/Al/TiO₂, ZnS/Ag/ZnS, ZnS/A1/ZnS.

In some embodiments, in the above steps, the step of preparing the hole functional layer includes: on the surface of the substrate such as ITO or the light-emitting layer, depositing a solution of the prepared hole injection or hole transport material into a film through a process such as drop coating, spin coating, immersing, plastic coating, printing, and evaporation; controlling the film thickness by adjusting the concentration of the solution, the deposition speed and the deposition time, and then carrying out a thermal annealing treatment at an appropriate temperature.

In some embodiments, the hole functional layer includes a hole transport layer and a hole injection layer.

In some embodiments, the hole injection layer includes, but is not limited to, one or more of an organic hole injection material, a doped or undoped transition metal oxide, and a doped or undoped metal chalcogenide. In some specific embodiments, the organic hole injection material includes, but is not limited to, one or more of poly(3,4-ethylenedioxythiophene) polystyrene sulfonate (PEDOT:PSS), copper phthalocyanine (CuPc), 2,3,5,6-tetrafluoro-7,7′,8,8′-tetracyano-quinodimethane (F4-TCNQ), and 1,4,5,8,9,12-hexaazatriphenylene-2,3,6,7,10,11-hexacarbonitrile (HATCN). In some specific embodiments, the transition metal oxide includes, but is not limited to, one or more of MoO₃, VO₂, WO₃, CrO₃, and CuO. In some specific embodiments, the metal chalcogenide includes, but is not limited to, one or more of MoS₂, MoSe₂, WS₂, WSe₂, and CuS.

In some embodiments, the hole transport layer may be selected from an organic material with hole transport capability and/or an inorganic material with hole transport capability. In some specific embodiments, the organic material with hole transport capability includes but is not limited to one or more of poly(9,9-dioctylfluorene-co-N-(4-sec-butylphenyl)-diphenylamine) (TFB), polyvinylcarbazole (PVK), poly(N,N′-bis(4-butylphenyl)-N,N′-bis(phenyl)-benzidine (poly-TPD), poly(9,9-dioctylfluorene-co-bis-N,N-phenyl-1,4-phenylenediamine) (PFB), 4,4′,4″-tris(carbazol-9-yl)triphenylamine (TCTA), 4,4-bis(9-carbazolyl)-bisphenyl (CBP), N,N′-diphenyl-N,N′-bis(3-methylphenyl)-1,1′-biphenyl-4,4′-di amine (TPD), and N,N′-bis(1-naphthyl)-N,N′-diphenyl-1, 1 ‘-biphenyl-4, 4’-diamine (NPB). In some specific embodiments, the inorganic material with hole transport capability includes but are not limited to doped graphene, undoped graphene, C60, doped or undoped MoO₃, VO₂, WO₃, CrO₃, CuO, MoS₂, MoSe₂, WS₂, WSe₂, and CuS.

In some embodiments, in the above steps, the step of preparing the light-emitting layer includes: on the surface of the hole transport layer or the electron transport layer, depositing a solution of the light-emitting substance prepared at a certain concentration into a film through a process such as drop coating, spin coating, immersing, plastic coating, printing, and evaporation, controlling the film thickness to about 20 nm-60 nm by adjusting the concentration of the solution, the deposition speed and the deposition time, and drying at an appropriate temperature.

In some embodiments, a quantum-dot material is included in the light-emitting layer, and the quantum-dot material includes but is not limited to at least one of a semiconductor compound of group II-IV, group II-VI, group II-V, group III-V, group IV-VI, group group II-IV-VI, and group II-IV-V, or a core-shell semiconductor compound composed of at least two of the above semiconductor compounds. In some specific embodiments, the quantum-dot functional layer material is at least one semiconductor nanocrystalline compound selected from CdSe, CdS, CdTe, ZnO, ZnSe, ZnS, ZnTe, HgS, HgSe, HgTe, and CdZnSe, or a semiconductor nanocrystalline compound consists of at least two of the above compositions in a structure such as a mixed structure, gradient mixed structure, core-shell structure, or joint structure. In other specific embodiments, the quantum-dot functional layer material is at least one semiconductor nanocrystalline compound selected from InAs, InP, InN, GaN, InSb, InAsP, InGaAs, GaAs, GaP, GaSb, AlP, AN, AlAs, AlSb, CdSeTe, and ZnCdSe, or a semiconductor nanocrystalline compound consists of at least two of the above compositions in a structure such as a mixed structure, gradient mixed structure, core-shell structure, or joint structure. In other embodiments, the quantum-dot functional layer material is at least one selected from a perovskite nanoparticle material (especially a luminescent perovskite nanoparticle material), a metal nanoparticle material, and a metal-oxide nanoparticle material. Each of the above quantum-dot materials has the characteristics of quantum dots with good photoelectric performance.

In some embodiments, the particle size of the quantum-dot material ranges from 2 nm to 10 nm. If the particle size is too small, the film formability of the quantum-dot material becomes poorer, and the energy resonance transfer effect between quantum-dot particles is significant, which is not conducive to the application of the material, and if the particle size is too large, the quantum effect of the quantum-dot material will be weakened, resulting in a decrease in the photoelectric performance of the material.

In some embodiments, the obtained display device is encapsulated, and the encapsulation can be carried out by a conventional machine or manually. In the encapsulation environment, the oxygen content and water content are both lower than 0.1 ppm to ensure the stability of the device.

In some specific embodiments, as shown in FIG. 2, the display device has a conventional structure, including an anode disposed on a substrate, and a hole functional layer such as a hole injection layer and a hole transport layer deposited on the surface of the anode, a light-emitting layer deposited on the surface of the hole functional layer, an electron functional layer such as an electron transport layer deposited on the surface of the light-emitting layer, and a cathode deposited on the surface of the electron functional layer.

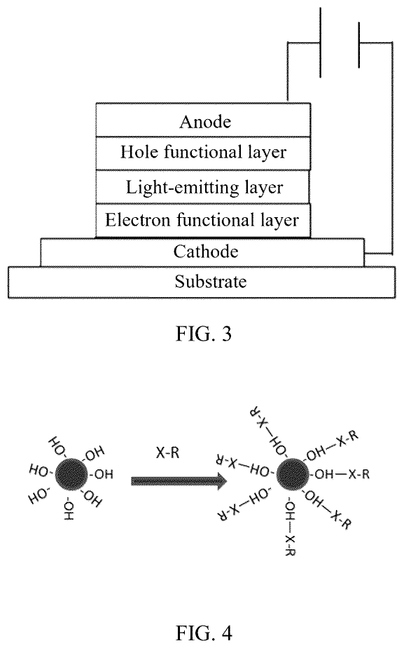

In other specific embodiments, as shown in FIG. 3, the display device has an inverted structure, including a substrate, a cathode deposited on the surface of the substrate, an electron functional layer such as an electron transport layer deposited on the surface of the cathode, a light-emitting layer deposited on the surface of the electron functional layer, a hole functional layers such as a hole transport layer and a hole injection layer deposited on the surface of the light-emitting layer, and an anode deposited on the surface of the hole functional layer.

In addition, an embodiment of the present application also provides a display device, which is manufactured by the above-mentioned method for manufacturing a display device.

The display device provided by the embodiment of the present application includes an anode, a hole functional layer, a light-emitting layer, an electron functional layer, and a cathode that are stacked and laminated in sequence. The electron functional layer adopts the above-mentioned electron transport material with small and uniform particle size, so the prepared electron transport layer has good compactness and good stability, and the contact interface with the adjacent functional layer is optimized to improve the migration and transmission of carriers in the device.

In order to make the details and operations of above-mentioned implementations of the present application clearly understood by those skilled in the art, as well as to significantly show the performance of the electron transport material and a preparation method thereof and a manufacturing method for a display device provided by the embodiments of the present application, the above technical proposals are exemplified through various examples below.

### Example 1

An electron transport material, prepared by the following steps:
\textcircled{1} 3 mmol of zinc acetate dihydrate was weighed and placed in a three-neck flask with the addition of 30 ml of ultra-dry solvent DMSO, and was dissolved to obtain a metal salt solution;
\textcircled{2}5 mmol of tetramethylammonium hydroxide (TMAH) was weighed and placed in a plastic beaker, with the addition of 10 ml of ultra-dry ethanol, and was dissolved to obtain an alkaline solution;
\textcircled{3} the zinc acetate solution was placed in a water bath at 50° C., stirred, and the TMAH solution was dropped into the zinc acetate solution using a constant pressure dropper when the temperature is constant;
\textcircled{4} after stirring and reacting for 0.5 hr, 1 hr, 2 hrs, and 5 hrs, respectively, diethylamine was added, and the respective molar ratios of zinc to diethylamine were 1:5, 1:20, and 1:50 respectively, and the reaction was continued to 20 hrs; specifically as shown in Table 1; and
\textcircled{5} the stirring was stopped, the solution was poured into a centrifuge tube with the addition of excess ethyl acetate to obtain a turbid solution, centrifuged at 3000 rpm, the supernatant was discarded, an appropriate amount of ultra-dry ethanol was added, and the precipitate was redissolved to obtain an ethanol solution of zinc oxide.

A display device, prepared by the following steps:
\textcircled{6} On an ITO substrate, PEDOT:PSS was spin-coated at 5000 rpm for 30 seconds, then heated at 150° C. for 15 minutes with a thickness of 20 nm to form a hole injection layer;
\textcircled{7} TFB (8 mg/mL) was spin-coated at 3000 rpm for 30 seconds, then heated at 150° C. for 30 minutes with a thickness of 30 nm to form a hole transport layer;

\textcircled{8} quantum dots (20 mg/mL) were spin-coated at a speed of 2000 rpm for 30 seconds with a thickness of 30 nm to form a quantum-dot light-emitting layer;
\textcircled{9} the ethanol solution of zinc oxide (30 mg/mL) in Example 1 was spin-coated at a speed of 3000 rpm for 30 seconds, and then treated on a vacuum annealing table at 80° C. and 0.001 Pa for 2 hrs with a thickness of 40 nm to form an electron transport layer;
\textcircled{10} an electrode was evaporated on the ETL layer and encapsulated to obtain a display device.

### Example 2

An electron transport material, a preparation method thereof differs from that in Example 1 in that: chlorobenzene was added as a capping agent in step \textcircled{4}, and the specific addition time and molar ratio were as shown in Table 2.

A display device, a preparation method thereof differs from that in Example 1 in that: the electron transport material prepared in Example 2 was used in step \textcircled{9}.

### Example 3

An electron transport material, a preparation method thereof differs from that in Example 1 in that: bromobenzene was added as a capping agent in step \textcircled{4}, and the specific addition time and molar ratio were as shown in Table 3.

A display device, a preparation method thereof differs from that in Example 1 in that: the electron transport material prepared in Example 3 was used in step \textcircled{9}.

### Example 4

An electron transport material, a preparation method thereof differs from that in Example 1 in that: PVP polyvinylpyrrolidone was added as a capping agent in step \textcircled{4}, and the specific addition time and molar ratio were as shown in Table 4.

A display device, a preparation method thereof differs from that in Example 1 in that: the electron transport material prepared in Example 4 was used in step \textcircled{9}.

### Comparative Example 1

An electron transport material, a preparation method thereof differs from that in Example 1 in that: the capping agent was added after stirring and reacting for 10 hrs and 15 hrs respectively in step \textcircled{4}, as shown in Table 1.

A display device, a preparation method thereof differs from that in Example 1 in that: the electron transport material prepared in Comparative Example 1 was used in step \textcircled{9}.

### Comparative Example 2

An electron transport material, a preparation method thereof differs from that in Example 2 in that: the capping agent was added after stirring and reacting for 10 hrs and 15 hrs respectively in step \textcircled{4}, as shown in Table 2.

A display device, a preparation method thereof differs from that in Example 1 in that: the electron transport material prepared in Comparative Example 2 was used in step \textcircled{9}.

### Comparative Example 3

An electron transport material, a preparation method thereof differs from that in Example 3 in that: the capping agent was added after stirring and reacting for 10 hrs and 15 hrs respectively in step \textcircled{4}, as shown in Table 3.

A display device, a preparation method thereof differs from that in Example 1 in that: the electron transport material prepared in Comparative Example 3 was used in step \textcircled{9}.

### Comparative Example 4

An electron transport material, a preparation method thereof differs from that in Example 4 in that: the capping agent was added after stirring and reacting for 10 hrs and 15 hrs respectively in step \textcircled{4}, as shown in Table 4.

A display device, a preparation method thereof differs from that in Example 1 in that: the electron transport material prepared in Comparative Example 4 was used in step \textcircled{9}.

### Comparative Example 5

An electron transport material, a preparation method thereof differs from that in Example 1 in that: no capping agent was added in step \textcircled{4}, and step \textcircled{5} was carried out after reacting for 0.5 hr, 1 hr, 2 hrs, 5 hrs, 10 hrs, 15 hrs, and 20 hrs.

A display device, a preparation method thereof differs from that in Example 1 in that: the electron transport material prepared in Comparative Example 5 was used in step \textcircled{9}.

In order to verify the progress of the examples of the present application, the particle size of the metal oxide particles in the electron transport layer of the display devices prepared in Examples 1 to 4 and Comparative Examples 1 to 4 was measured, and the test results are shown in Tables 1 to 4 below.

TABLE 1

| | | Addition time/h | | | | | | |
|---|---|---|---|---|---|---|---|---|
| | | | | | | Comparative | | |
| | | Example 1 | | | | Example 1 | | |
| Addition amount/molar ratio | | 0.5 hr | 1 hr | 2 hrs | 5 hrs | 10 hrs | 15 hrs | 20 hrs |
| Example 1 | Zn:diethyl- | 2-8 | 3-11 | 6-20 | 9-25 | 12-27 | 14-28 | 20-30 |
| | amine = 1:5 | nm | nm | nm | nm | nm | nm | nm/ |
| | Zn:diethyl- | 2-5 | 2-9 | 5-16 | 7-21 | 10-26 | 12-27 | 22-28 |
| | amine = 1:20 | nm | nm | nm | nm | nm | nm | nm/ |
| | Zn:diethyl- | 1-3 | 1-5 | 5-12 | 7-16 | 11-25 | 10-29 | 24-30 |
| | amine = 1:50 | nm | nm | nm | nm | nm | nm | nm/ |
| Comparative | Zn:diethyl- | 12-25 | 13-30 | 9-29 | 11-29 | 8-30 | 14-30 | 15-32 |
| Example 5 | amine = 1:0 | nm | nm | nm | nm | nm | nm | nm |

TABLE 2

| | | Addition time/h | | | | | | |
|---|---|---|---|---|---|---|---|---|
| | | | | | | Comparative | | |
| | | Example 2 | | | | Example 2 | | |
| Addition amount/molar ratio | | 0.5 hr | 1 hr | 2 hrs | 5 hrs | 10 hrs | 15 hrs | 20 hrs |
| Example 2 | Zn:chloro- | 1-6 | 3-13 | 6-21 | 9-24 | 14-27 | 13-28 | 19-30 |
| | benzene = 1:5 | nm | nm | nm | nm | nm | nm | nm/ |
| | Zn:chloro- | 1-5 | 2-10 | 5-15 | 8-21 | 12-26 | 12-28 | 20-35 |
| | benzene = 1:20 | nm | nm | nm | nm | nm | nm | nm/ |
| | Zn:chloro- | 1-3 | 1-4 | 5-10 | 8-16 | 11-26 | 10-30 | 22-37 |
| | benzene = 1:50 | nm | nm | nm | nm | nm | nm | nm/ |
| Comparative | Zn:chloro- | 10-24 | 7-28 | 13-32 | 11-30 | 15-34 | 9-28 | 13-35 |
| Example 5 | benzene = 1:0 | nm | nm | nm | nm | nm | nm | nm |

TABLE 3

| | | Addition time/h | | | | | | |
|---|---|---|---|---|---|---|---|---|
| | | | | | | Comparative | | |
| | | Example 3 | | | | Example 3 | | |
| Addition amount/molar ratio | | 0.5 hr | 1 hr | 2 hrs | 5 hrs | 10 hrs | 15 hrs | 20 hrs |
| Example 3 | Zn:bromo- | 1-9 | 3-14 | 6-22 | 10-24 | 11-26 | 13-29 | 20-33 |
| | benzene = 1:5 | nm | nm | nm | nm | nm | nm | nm/ |
| | Zn:bromo- | 1-4 | 2-12 | 6-15 | 8-19 | 9-26 | 12-27 | 24-32/ |
| | benzene = 1:20 | nm | nm | nm | nm | nm | nm | |
| | Zn:bromo- | 1-3 | 2-3 | 4-8 | 7-16 | 8-26 | 10-25 | 23-30 |
| | benzene = 1:50 | nm | nm | nm | nm | nm | nm | nm/ |
| Comparative | Zn:bromo- | 10-28 | 12-31 | 11-33 | 9-30 | 13-34 | 10-29 | 8-30 |
| Example 5 | benzene = 1:0 | nm | nm | nm | nm | nm | nm | nm |

TABLE 4

| | | Addition time/h | | | | | | |
|---|---|---|---|---|---|---|---|---|
| | | | | | | Comparative | | |
| | | Example 4 | | | | Example 4 | | |
| Addition amount/molar ratio | | 0.5 hr | 1 hr | 2 hrs | 5 hrs | 10 hrs | 15 hrs | 20 hrs |
| Example 4 | Zn:PVP = 1:5 | 0.8-9 | 3-12 | 6-20 | 10-22 | 11-25 | 13-27 | 22-28 |
| | | nm | nm | nm | nm | nm | nm | nm/ |
| | Zn:PVP = 1:20 | 0.5-4 | 1-10 | 4-12 | 8-17 | 9-20 | 12-26 | 23-29 |
| | | nm | nm | nm | nm | nm | nm | nm/ |
| | Zn:PVP = 1:50 | 0.5-2 | 1-3 | 4-6 | 6-15 | 7-18 | 10-23 | 24-32 |
| | | nm | nm | nm | nm | nm | nm | nm/ |
| Comparative | Zn:PVP = 1:0 | 10-30 | 8-29 | 9-32 | 7-31 | 9-35 | 12-33 | 14-34 |
| Example 5 | | nm | nm | nm | nm | nm | nm | nm |

From the above test results in Tables 1 to 4, it can be found that the electron transport materials prepared after adding a capping agent in Examples 1 to 4 and Comparative Examples 1 to 4 of the present application have small particle sizes and narrow particle size distributions. In Comparative Example 5 without the addition of a capping agent, the electron transport material prepared had a wide particle size distribution, poor uniformity, and a larger particle size.

The present application has tested the external quantum efficiency (EQE) and lifetime T95@1000 nit of some display devices in Examples 1 to 4 and Comparative Examples 1 to 5 respectively, and the test results are shown in the following table:

TABLE 5

| | Synthesis conditions of ZnO | Device | Device lifetime |
|---|---|---|---|
| | for optimal device | EQE % | T95@1000nit hrs |
| Example 1 | Zn:diethylamine = 1:50 | 16 | 10000 |
| | (molar ratio), | | |
| | addition time: after | | |
| | reacting for 2 hrs | | |
| | Zn:diethylamine = 1:20 | 19 | 9000 |
| | (molar ratio), | | |
| | addition time: after | | |
| | reacting for 1 hr | | |
| | Zn:diethylamine = 1:50 | 18 | 11000 |
| | (molar ratio), | | |
| | addition time: after | | |
| | reacting for 0.5 hr | | |
| Example 2 | Zn:chlorobenzene = 1:20 | 18 | 12000 |
| | (molar ratio), | | |
| | addition time: after | | |
| | reacting for 2 hrs | | |
| | Zn:chlorobenzene = 1:50 | 18 | 10500 |
| | (molar ratio), | | |
| | addition time: after | | |
| | reacting for 2 hrs | | |
| | Zn:chlorobenzene = 1:50 | 20 | 15000 |
| | (molar ratio), | | |
| | addition time: after | | |
| | reacting for 0.5 hr | | |
| Example 3 | Zn:bromobenzene = 1:50 | 18 | 13400 |
| | (molar ratio), | | |
| | addition time: after | | |
| | reacting for 5 hrs | | |
| | Zn:bromobenzene = 1:50 | 18 | 12000 |
| | (molar ratio), | | |
| | addition time: after | | |
| | reacting for 2 hrs | | |
| | Zn:bromobenzene = 1:50 | 19 | 13600 |
| | (molar ratio), | | |
| | addition time: after | | |
| | reacting for 0.5 hr | | |
| Example 4 | Zn:PVP = 1:50 (molar | 21 | 14800 |
| | ratio), addition | | |
| | time: after reacting | | |
| | for 0.5 hr | | |
| | Zn:PVP = 1:20 (molar | 19 | 16500 |
| | ratio), addition | | |
| | time: after reacting | | |
| | for 2 hrs | | |
| | Zn:PVP = 1:50 (molar | 17 | 10800 |
| | ratio), addition time: | | |
| | after reacting for 5 hrs | | |
| Comparative | No capping agent (5 hrs) | 12 | 3000 |
| Example 5 | | | |
| Comparative | Zn:diethylamine = 1:20 | 13 | 3500 |
| Example 1 | (molar ratio), | | |
| | addition time: after | | |
| | reacting for 10 hrs | | |
| | Zn:diethylamine = | 14 | 3250 |
| | 1:20 (molar ratio), | | |
| | addition time: after | | |
| | reacting for 15 hrs | | |
| Comparative | Zn:chlorobenzene = | 10 | 3300 |
| Example 2 | 1:20 (molar ratio), | | |
| | addition time: after | | |
| | reacting for 10 hrs | | |
| | Zn:chlorobenzene = | 11 | 2800 |
| | 1:20 (molar ratio), | | |
| | addition time: after | | |
| | reacting for 15 hrs | | |
| Comparative | Zn:bromobenzene = | 12 | 3900 |
| Example 3 | 1:20 (molar ratio), | | |
| | addition time: after | | |
| | reacting for 10 hrs | | |
| | Zn:bromobenzene = | 15 | 4000 |
| | 1:20 (molar ratio), | | |
| | addition time: after | | |
| | reacting for 15 hrs | | |
| Comparative | Zn:PVP = 1:20 (molar | 13 | 3120 |
| Example 4 | ratio), addition | | |
| | time: after reacting for 10 hrs | | |
| | Zn:PVP = 1:20 (molar | 12 | 3280 |
| | ratio), addition | | |
| | time: after reacting for 15 hrs | | |

From the above test results in Table 5, it can be found that the external quantum efficiency and device lifetime of the display devices prepared from the electron transport materials in Examples 1˜4 are not affected by the addition of the capping agent, instead, the optoelectronic performance of the device has been enhanced to a certain extent due to the improvement of the density of the electron transport film layer. In Comparative Examples 1˜4 where the capping agents were added in the later stage of synthesis (10 hrs, 15 hrs), since the particles in the later stage of synthesis have ripened and grown in size, the particle size of the material is about 20 nm-30 nm, and the electron transport layer with a larger particle size will lead to an increase in the conductivity thereof, resulting in a severe excess of electrons in the device, thereby reducing the efficiency and lifespan of the device. In comparison, since no capping agent was added at different synthesis times in Comparative Example 5, the particle size distribution of the electron transport material was wider after the formation of the film. This is because the particles without a capping agent have higher surface energy, which causes aggregation in the material during storage and the film formation, resulting in particle growth, uneven distribution of particles, and the existence of particles having large particle size, thereby affecting the quality of film formation in the material, reducing the photoelectric performance of the device, and even causing a short circuit of the device that leads to serious leakage and deterioration of the performance of the device.

The above are only the preferred embodiments of the present application, not to limit the present application, any modifications, equivalent substitutions and improvements made without departing from the spirit and principles of the present application are within the scope of protection of in the present application.

What is claimed is:

1. A preparation method for an electron transport material, comprising the following steps:
obtaining a metal salt solution and an alkaline solution; and
after mixing the metal salt solution and the alkaline solution, adding a capping agent during a reaction between a metal salt and an alkaline substance to continue the reaction, so as to obtain a metal-oxide electron transport material having a surface bonded with the capping agent;
wherein, the capping agent is at least one selected from an alkane containing a nitrogen atom or a halogen atom, a cycloalkane containing a nitrogen atom or a halogen atom, and a polymer containing a nitrogen atom or a halogen atom.

2. The preparation method for an electron transport material according to claim 1, wherein in the capping agent, the number of carbon atoms in the alkane is 2 to 16; the number of carbon atoms in the cycloalkane is 3 to 16.

3. The preparation method for an electron transport material according to claim 1, wherein the alkane comprises a branched chain.

4. The preparation method for an electron transport material according to claim 1, wherein the polymer has a boiling point of no higher than 300° C.

5. The preparation method for an electron transport material according to claim 2, wherein the capping agent is at least one selected from diethylamine, chlorobenzene, bromobenzene, and polyvinylpyrrolidone.

6. The preparation method for an electron transport material according to claim 1, wherein the step of adding a capping agent during the reaction between the metal salt and the alkaline substance to continue the reaction comprises: adding the capping agent after 0.5 to 5 hrs since the metal salt reacts with the alkaline substance to continue the reaction for 15 to 20 hrs.

7. The preparation method for an electron transport material according to claim 1, wherein a molar ratio of a metal element in the metal salt to the capping agent is 1:(5-50).

8. The preparation method for an electron transport material according to claim 6 or 7, wherein the metal salt is at least one selected from a zinc salt, a titanium salt, a tin salt, a zirconium salt, and an indium salt;
and/or, a solvent in the metal salt solution is at least one selected from dimethyl sulfoxide, N,N-dimethylformamide, and tetrahydrofuran;
and/or, the alkaline substance is at least one selected from tetramethylammonium hydroxide, lithium hydroxide, potassium hydroxide, and sodium hydroxide;
and/or, a solvent in the alkaline solution is at least one selected from ethanol, methanol, propanol, isopropanol, and butanol.

9. The preparation method for an electron transport material according to claim 8, wherein the step of mixing the metal salt solution and the alkaline solution comprises: adding the alkaline solution dropwise to the metal salt solution at a temperature of 40° C. to 60° C. for mixing.

10. The preparation method for an electron transport material according to claim 8, wherein after the metal salt solution and the alkaline solution are mixed, a molar ratio of the metal salt to the alkaline substance in a mixed solution is 1:(1.2-1.8).

11. The preparation method for an electron transport material according to claim 8, wherein the metal salt further comprises at least one of a magnesium salt, an aluminum salt, a calcium salt, and a lithium salt.

12. An electron transport material, wherein the electron transport material comprises a metal oxide and a capping agent bonded to a surface of the metal oxide, the capping agent is at least one selected from an alkane containing a nitrogen atom or a halogen atom, a cycloalkane containing a nitrogen atom or a halogen atom, and a polymer containing a nitrogen atom or a halogen atom.

13. The electron transport material according to claim 12, wherein the electron transport material has a particle size of 1 μm-25 μm.

14. The electron transport material according to claim 12, wherein the metal oxide comprises: at least one of ZnO, TiO₂, SnO, ZrO₂, In₂O₃, ZnMgO, and AlZnO.

15. The electron transport material according to claim 12, wherein the capping agent is at least one selected from diethylamine, chlorobenzene, bromobenzene, and polyvinylpyrrolidone.

16. The electron transport material according to claim 12, wherein the capping agent is bonded to the surface of the metal oxide through the nitrogen atom or the halogen atom.

17. A manufacturing method for a display device, comprising the following steps:
sequentially stacking a hole functional layer and a light-emitting layer on a substrate containing an anode;
depositing an electron transport material prepared by the preparation method according to claim 1 on a surface of the light-emitting layer away from the hole functional layer, and carrying out a vacuum annealing treatment to obtain an electron transport layer made of a metal oxide; and
preparing a cathode on a surface of the electron transport layer to obtain a display device;
alternatively,
depositing an electron transport material prepared by the preparation method according to claim 1 on a surface of a cathode on a substrate, and carrying out a vacuum annealing treatment to obtain an electron transport layer made of a metal oxide; and
sequentially stacking a light-emitting layer, a hole functional layer, and an anode on a surface of the electron transport layer to obtain a display device.

18. The manufacturing method for a display device according to claim 17, wherein conditions of the vacuum annealing treatment comprise: annealing at a temperature of 70° C.-90° C. for 0.5 hr-2 hrs under a vacuum degree lower than or equal to 0.0001 Pa.

19. The preparation method for an electron transport material according to claim 3, wherein the capping agent is at least one selected from diethylamine, chlorobenzene, bromobenzene, and polyvinylpyrrolidone.

20. The preparation method for an electron transport material according to claim 4, wherein the capping agent is at least one selected from diethylamine, chlorobenzene, bromobenzene, and polyvinylpyrrolidone.
